(19) United States
(12) Patent Application Publication
(10) Pub. No.: US 2015/0263670 A1
(43) Pub. Date: Sep. 17, 2015

(54) Frequency Modulation Based on Two Path Modulation

(71) Applicant: Uniband Electronic Corp., Hsin-Chu (TW)

(72) Inventors: Yiping Fan, Hsinchu City (TW); Chun-Yuan Lin, Pingtung County (TW); Sheng-Wei Chiang, Hsinchu County (TW); Yi-Chun Lu, Taoyuan County (TW)

(73) Assignee: Uniband Electronic Corp., Hsin-Chu (TW)

(21) Appl. No.: 14/203,572

(22) Filed: Mar. 11, 2014

(51) Int. Cl. H03B 5/12

(52) U.S. Cl. CPC H03B 5/1206

(57) ABSTRACT

A two path direct frequency modulation system is disclosed. The system includes a Varactor, a voltage-controlled oscillator (VCO) calibration capacitor bank including a first plurality of switchable capacitors, and a frequency deviation capacitor bank including a second plurality of switchable capacitors. The method includes switching on or off a number of the first plurality of switchable capacitors to obtain a desired frequency band and determining number of cycles within a first predetermined time to obtain a first count, switching on or off a number of the first plurality of switchable capacitors or of the second plurality of switchable capacitors to change the desired frequency band and determining number of cycles within a second predetermined time to obtain a second count, and modulating a data signal by switching on or off a switchable capacitors of the second plurality of switchable capacitors according to the first and the second count.

### BACKGROUND OF THE INVENTION

1. Field of the Invention

This application relates to a method of operating a two path direct frequency modulation system, and more specifically, a system and method of operating the two path direct frequency modulation system digitally.

2. Description of the Prior Art

Frequency modulations such as Frequency Shift Keying (FSK), Minimum Shift Keying (MSK), Gaussian frequency shift keying (GFSK), and Gaussian Minimum Shift Keying (GMSK) are used in wireless communications for their simplicity and low cost design. When the frequency modulation index is 0.5, FSK becomes MSK. That is, MSK is a special case of FSK.

In a conventional design, FSK is typically implemented with direct voltage-controlled oscillator (VCO) modulation or I/Q quadrature modulation. When the data rate is low, such as less than a phase-lock loop (PLL) bandwidth, it is very efficiently implemented with a Sigma-Delta modulator, which is often used to achieve a fractional frequency synthesizer. This later approach effectively combines frequency synthesis and frequency modulation, such as FSK and its variants.

However, when the data rate exceeds the PLL bandwidth, this later approach will not work, since the signal energy is filtered out by the loop filter.

To compensate for the filtered signal energy, a two path direct frequency modulation system 100 such as is shown in FIG. 1 was introduced, where a second signal path is added to the Varactor of the VCO.

The two path direct frequency modulation system 100 includes a first path typically uses a digital-to-analog converter (DAC) 140 to convert a digital signal output from the baseband modulator 110 into an analog signal, which is fed to the VCO's 120 input via the low-pass filter 135. Also is included is a second path where a baseband modulator 110 outputs to a Delta-Sigma Modulator 130. A prescaler 123 receives output from both the Delta-Sigma Modulator 130 and a divider 125 and outputs to the VCO 120 via a phase frequency detector 115, a charge pump 117, and a loop filter 119 coupled in series. A reference clock from a crystal oscillator (Ref Clock) is also inputted to the serially coupled phase frequency detector (PFD) 115, allowing the PFD 115 to output the phase error to the charge pump 117, the loop filter 119, and finally to the VCO 120 to correct VCO 120 frequency. The VCO 120 outputs to the divider 125, which in turn outputs the local oscillator (LO) signal LO output.

The first path has a high-pass characteristic and the second path has a low-pass characteristic. The desired result is the combination of the low-passed and high-passed signals and yields an undistorted signal at the VCO 120 output. Research has been done with this approach and the desired results can be achieved if the first path and the second path have a proper gain match.

FIG. 2 illustrates the VCO 120 of the frequency modulation system 100 of FIG. 1. The VCO 120 includes a Negative gm generator 250, an inductor 240, and voltage controlled variable capacitors (Varactor) 235, where the node Vtune between two Varactors 235 is used to tune capacitance of the Varactors 235 for Phase Lock Loop (PLL) locking 230. Coupled to the Varactor 235, the inductor 240, and the Negative gm generator 250, is a VCO calibration capacitor bank 220. The VCO calibration capacitor bank 220 may comprise resistors 271, a plurality of switchable capacitors comprising metal-insulator-metal (MIM) capacitors 275, and Complementary metal-oxide-semiconductor (CMOS) capacitors 277 as shown. Any type of capacitor or combination sets of capacitors can be used to implement the VCO calibration capacitor bank 220.

The VCO calibration capacitor bank 220 can be calibrated and selected to the desired frequency band, and then lock frequency according to the two path approach by controlling voltages applied to the Vtune node by inputs of the two paths as shown. The first path has a high-pass characteristic with digital signal flowing from the baseband modulator 110, converted by the DAC 140, and through the low-pass filter 135 to the Vtune node. The second path has a low-pass characteristic with voltage signal flowing through the charge pump 117 and loop filter 119 to the Vtune node. By controlling voltages of the first and second paths to the Vtune node, frequency of the VCO 120 is adjusted.

However, even with the dual path approach, there are still a significant number of analog circuits used. These analog circuits have a high current consumption, take up relatively large portions of valuable die space, and often contain active components which generate noise.

### SUMMARY OF THE INVENTION

A two path direct frequency modulation system is disclosed that includes an inductor, a Varactor coupled to the inductor, a voltage-controlled oscillator (VCO) calibration capacitor bank coupled to the Varactor and including a first plurality of switchable capacitors, and a frequency deviation capacitor bank coupled to the VCO calibration capacitor bank and including a second plurality of switchable capacitors. The frequency deviation capacitor bank is configured to modulate a data signal within the desired frequency band by adjusting how many switchable capacitors of the second plurality of switchable capacitors are switched on and how many switchable capacitors of the second plurality of switchable capacitors are switched off. A counting unit may be used to determine how many switchable capacitors of the second plurality of switchable capacitors are switched on and how many switchable capacitors of the second plurality of switchable capacitors are switched off during data signal modulation.

A method of operating a two path direct frequency modulation system is also disclosed. The two path direct frequency modulation system includes a Varactor, a voltage-controlled oscillator (VCO) calibration capacitor bank including a first plurality of switchable capacitors, and a frequency deviation capacitor bank including a second plurality of switchable capacitors. The method includes setting the Vtune to a predefined voltage, setting the VCO calibration capacitor bank to the calibrated value, switching on a predetermined number of switchable capacitors of the second plurality of switchable capacitors and determining number of cycles within a first predetermined time to obtain a first count, switching off a predetermined number of switchable capacitors of the second plurality of switchable capacitors to change the deviation frequency and determining number of cycles within a second predetermined time to obtain a second count, and modulating a data signal at the desired frequency band by switching on or off a predetermined number of switchable capacitors of the second plurality of switchable capacitors according to the first and the second count.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a related art two path direct frequency modulation system.

FIG. 2 illustrates the VCO of the frequency modulation system of FIG. 1.

FIG. 3 illustrates a two path frequency modulation system according to an embodiment of the present invention.

FIG. 4 illustrates the VCO of the frequency modulation system of FIG. 3.

FIG. 5 is a flow chart of calibrating and operating the two path frequency modulation system of FIG. 2.

FIG. 6 is a flow chart of calibrating and operating the two path frequency modulation system of FIG. 2.

### DETAILED DESCRIPTION

How to achieve a whole digitally controlled two path frequency modulation and its related calibration is the goal of this invention. In this new approach, instead of using a DAC to input the high pass signal into the varactor, a switched capacitor bank, which is digitally controlled, is used to achieve the required frequency deviation. Since the VCO's frequency is inversely proportional to the square root of L times C, where L is the inductor and C is the capacitor. When either value is changed, the oscillation frequency varies.

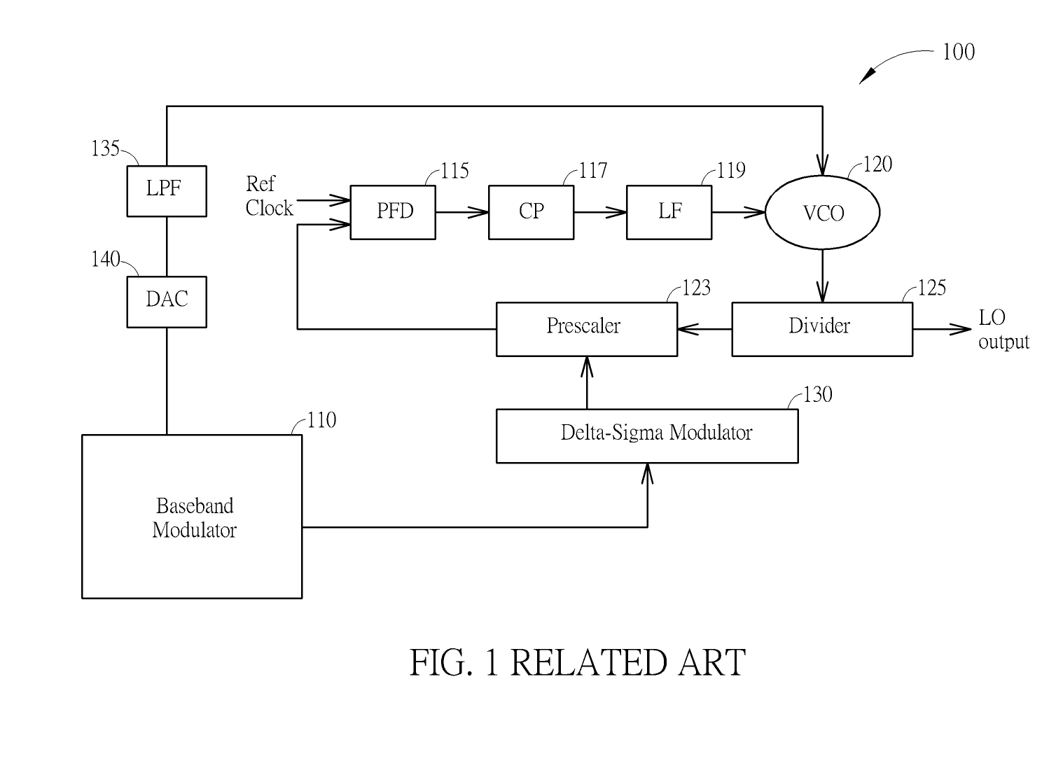

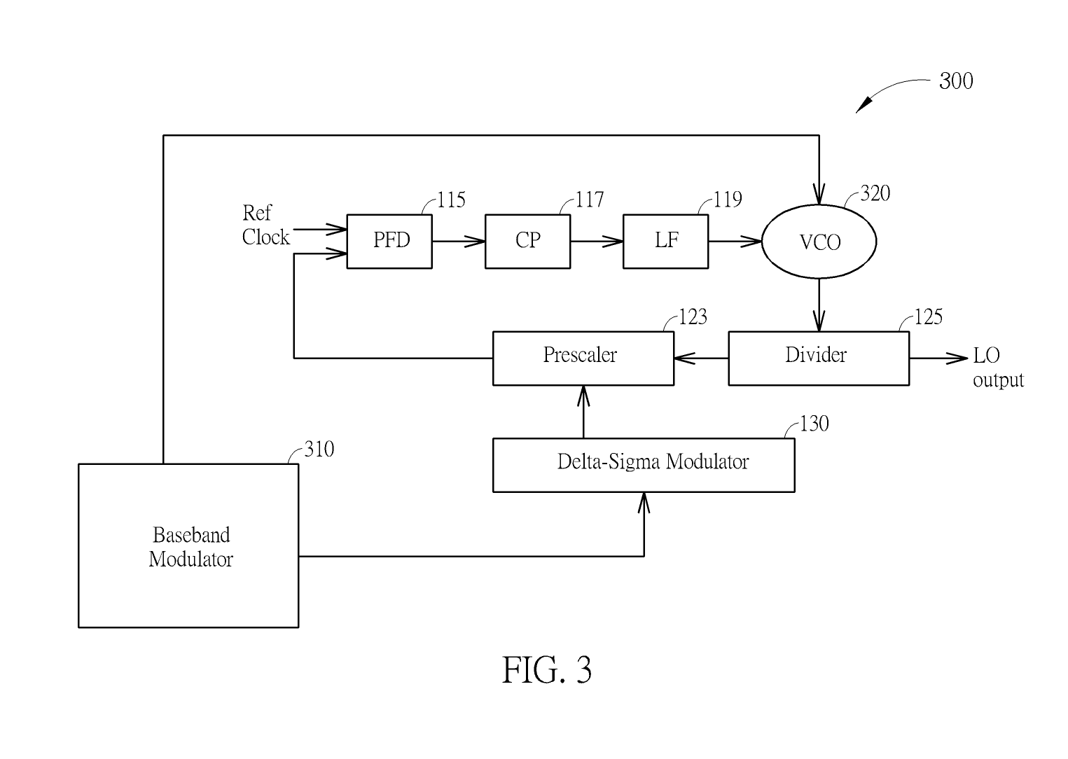

FIG. 3 illustrates a two path frequency modulation system 300 according to an embodiment of the present invention. Similarly to the frequency modulation system 100 of FIG. 1, the two path direct frequency modulation system 300 includes a second path where a baseband modulator 310 outputs to a Delta-Sigma Modulator 130. A prescaler 123 receives output from both the Delta-Sigma Modulator 130 and a divider 125 and outputs to the VCO 320 via a phase frequency detector 115, a charge pump 117, and a loop filter 119 coupled in series. A reference clock from a crystal oscillator (Ref Clock) is also inputted to the VCO 120 via the serially coupled phase frequency detector 115, the charge pump 117, and the loop filter 117. The VCO 320 outputs to the divider 125, which in turn outputs the local oscillator (LO) signal LO output.

A major difference between the frequency modulation system 100 of FIG. 1 and the frequency modulation system 300 of FIG. 3 is the first path, which feeds a digital control signal output from the baseband modulator 310 directly to the secondary switchable capacitor bank's input of VCO 320. No DAC or low-pass filter is required in the first path of this embodiment.

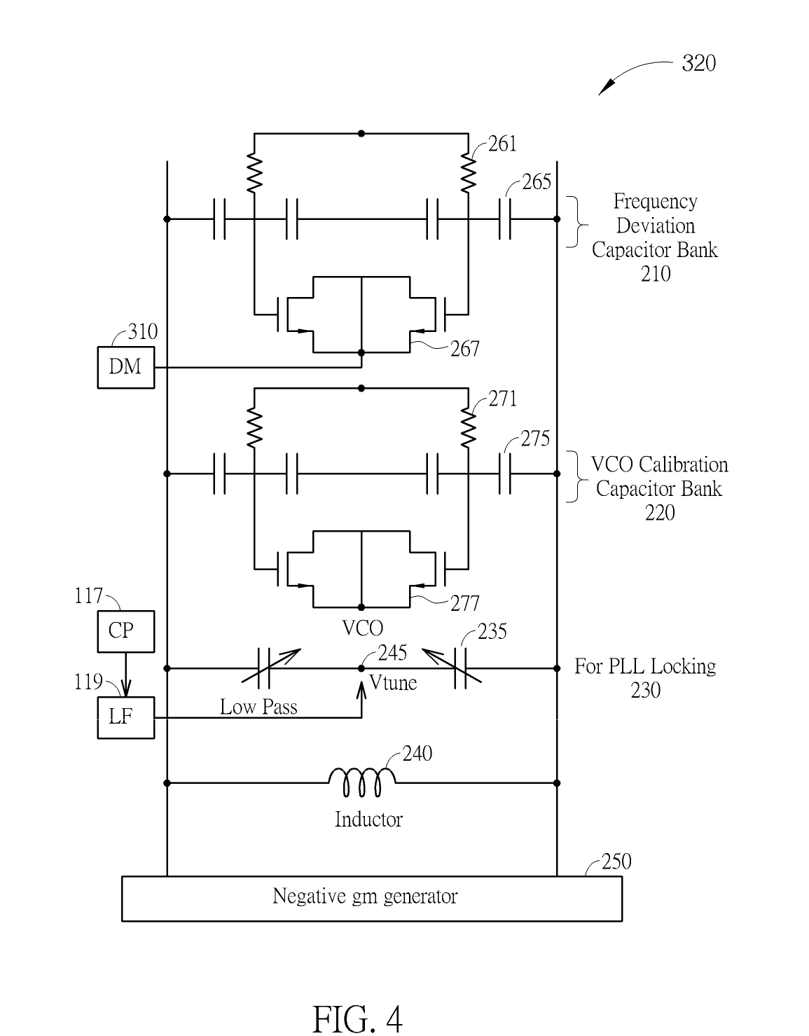

FIG. 4 illustrates the VCO 320 of the frequency modulation system 300 of FIG. 3. The VCO 320 includes the Negative gm generator 250, the inductor 240, and the Varactors 235. Vtune node 245 is the voltage node between two the Varactors 235 that is used for Phase Lock Loop (PLL) locking 230.

Because of the semi-conductor process, voltage and temperature contribute to the inductor and capacitor variation and some compensation circuit, such as a switched capacitor bank is used to reduce these variations in VCO 320 design as shown in FIG. 4.

The switched capacitor bank is achieved through the VCO calibration capacitor bank 220. The VCO calibration capacitor bank 220 may comprise resistors 271, a plurality of switchable capacitors constituted of MIM capacitor 275 and CMOS capacitor 277 coupled also as shown.

Another switchable capacitor bank coupled to the Varactor 235, inductor 240, and Negative gm generator 250, is the frequency deviation capacitor bank 210. The frequency deviation capacitor bank 210 may comprise resistors 261, a plurality of switchable capacitors which may be constituted of MIM capacitor 265 and CMOS capacitors 267 coupled as shown. The capacitors 265, 267, 275, and 277 are not limited to being of MIM and/or CMOS types and any type of capacitor or combination sets of capacitors can be used to implement both or either of the VCO calibration capacitor bank 220 and the frequency deviation capacitor bank 210.

The first path has a high-pass characteristic with digital signal flowing from the baseband modulator 310 directly to the switching devices 267 of the frequency deviation capacitor bank 210. The second path has a low-pass characteristic with voltage flowing through the charge pump 117 and loop filter 119 to the Varactor 235. By controlling voltages of the second path to the Vtune circuit 230, frequency of the VCO 320 can be controlled. The digital control signal output from the baseband modulator 310 to the switching devices 267 of the frequency deviation capacitor bank 210 can be used for data modulation by turning on and/or one at least one of the plurality of switchable capacitors 265.

Basically the two path frequency modulation system 300 shown in FIG. 3 uses two individual capacitor banks 210, 220 to achieve the two paths. The VCO calibration capacitor bank 220 can be calibrated and tuned to the desired frequency band. The frequency deviation capacitor bank 210 is used for modulating the data signal within the desired frequency band, and thus is preferably of higher resolution and greater sensitivity than is the VCO calibration capacitor bank 220. The frequency deviation capacitor bank 210 and the VCO calibration capacitor bank 220 is each and individually adjusted by turning off or on any number of the switchable capacitors 267 and/or 277 respectively.

A predetermined algorithm can be used to search for the number of switched on and off capacitors so that a desired frequency or range is achieved. A digital count circuit, which counts the VCO frequency, is an effective way to distinguish the frequency difference between the desired and measured frequencies, although there are other ways to achieve this goal, such as, inter alia, usage of a lookup table, and this disclosure is not limited to using a digital count circuit.

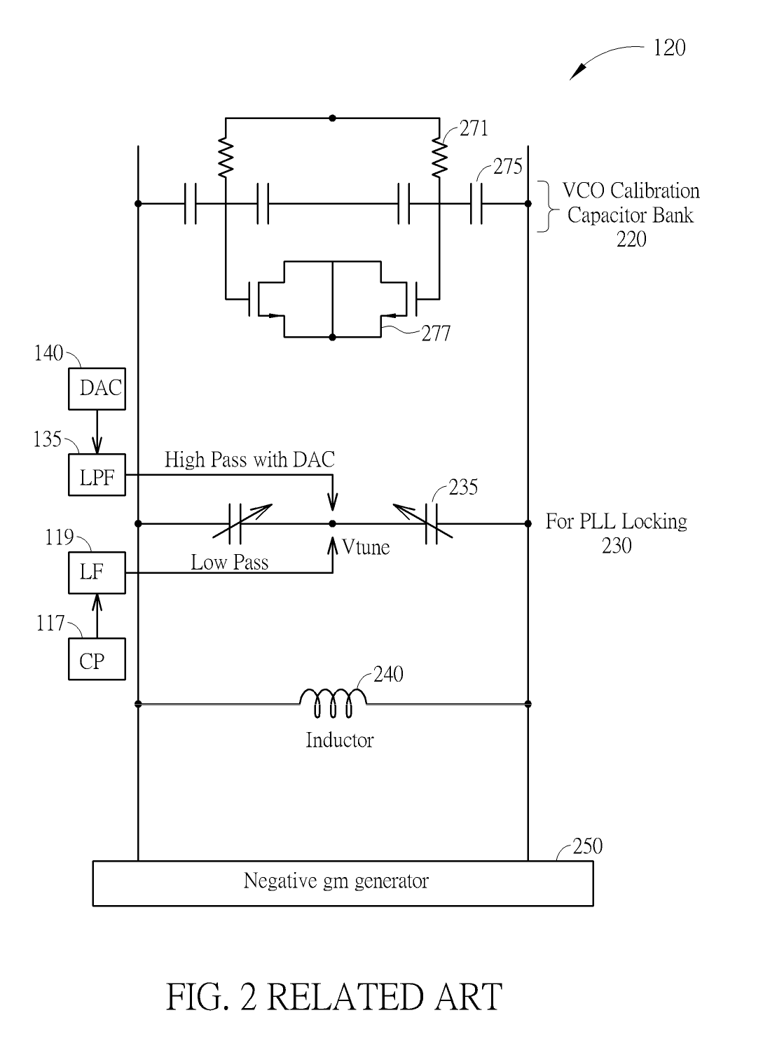

The length of a counting period determines the counted frequency resolution. A high frequency resolution also requires a big counter. This frequency compensation in VCO design is typically very coarse and switching on or off of one capacitor typically changes frequency of several dozen MHz or bigger. This capacitor bank for the VCO calibration is called herein the VCO calibration capacitor bank 220, as shown in FIG. 2.

However, in wireless communication, the VCO typically operates in a Giga Hz frequency range while the data rate is typical less a few Mbps, the resulted frequency deviation due to frequency modulation is negligible compared to the carrier frequency.

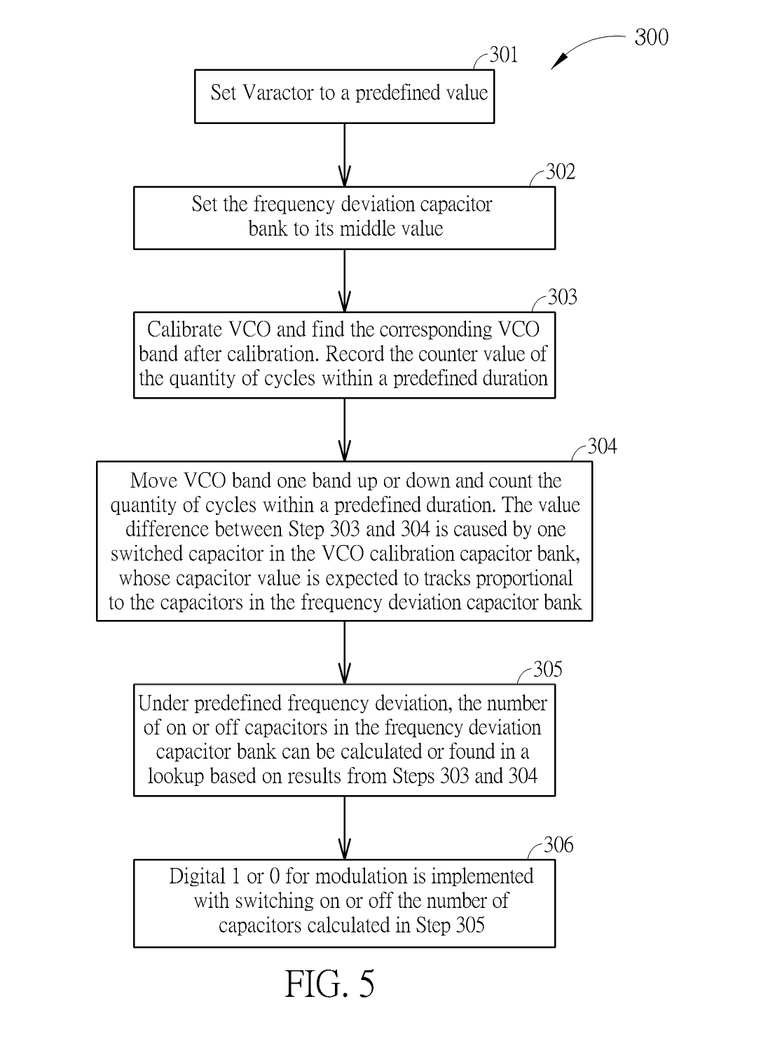

In this novel approach, a second capacitor bank, call the frequency deviation capacitor bank 210 is added to the VCO to control frequency deviation. Since changes in frequency due to changes in the frequency deviation capacitor bank 210 are much smaller as compared to the VCO calibration capacitor bank 220, the capacitor value the frequency deviation capacitor bank 210 is much smaller. The capacitor in the frequency deviation capacitor bank 210 may be of the same type as in the VCO calibration capacitor bank 220. If the capacitor variation of the frequency deviation capacitor bank 210 tracks the one in the VCO calibration capacitor bank 220, the flow chart 300 shown in FIG. 5 is one example that can be used to determine the required on and off capacitors in the frequency deviation capacitor bank 210. Flow chart 300 includes:

Step 301: Set Vtune to a predefined value, typically Vdd/2.

Step 302: Set the frequency deviation capacitor bank 210 to its middle value.

Step 303: Calibrate the VCO and find the corresponding VCO band after calibration. Record the counter value of the number of cycles within a predetermined time to determine a first count; this allows the optimal selection of VCO band for a particular channel chosen.

Step 304: Move the VCO band one band up or down (by switching on or off one of the switchable capacitors 275) and count the number of cycles with a predefined time to determine a second count. The value difference (count of number of cycles) between the first count and the second count is caused by one switched capacitor 275 in the VCO calibration capacitor bank 220, whose capacitor value is expected to track proportionally to the capacitors 265 in the frequency deviation capacitor bank 210.

Step 305: Under predefined frequency deviation, the number of on or off capacitors in the frequency deviation capacitor bank can be calculated or determined through a look-up table based on the first count, the second count, and/or the difference between the first and second counts.

Step 306: Digital 1 or 0 for modulation are implemented by switching on or off the number of capacitors calculated in Step 305.

The essence of the above calibration scheme is to use a large capacitor to estimate the small capacitor so that less time and simple counter can be used. The drawback is if the variation of the frequency does not track well to the VCO calibration capacitor bank, the accuracy of the frequency and quality of the transmitted signal will be compromised.

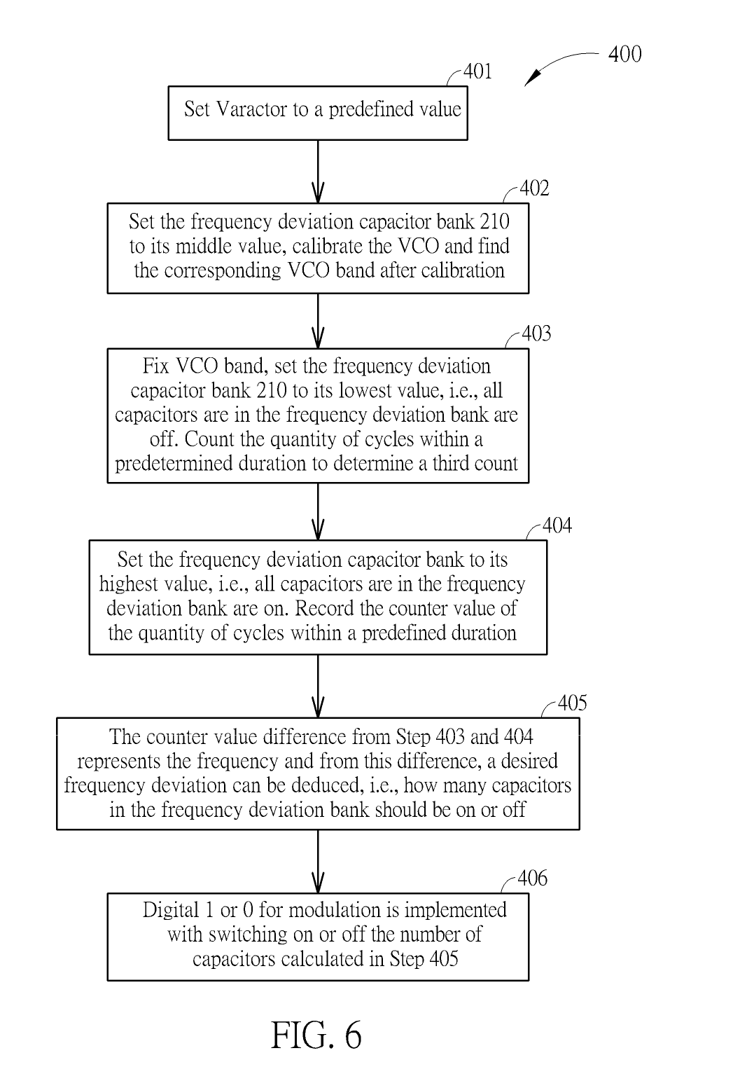

To solve this problem, a second calibration scheme is proposed as shown in FIG. 6. Flow chart 400 includes the following steps:

Step 401: Set Vtune to a predefined value, typically Vdd/2.

Step 402: Set the frequency deviation capacitor bank 210 to its middle value, calibrate the VCO and find the corresponding VCO band after calibration.

Step 403: Fix VCO band, set the frequency deviation capacitor bank 210 to its lowest value, i.e., all capacitors are in the frequency deviation bank are off. Count the number of cycles within a predetermined time to determine a third count.

Step 404: Set the frequency deviation capacitor bank 210 to its highest value, i.e., all capacitors are in the frequency deviation bank are on. Count the number of cycles with a predefined time to determine a fourth count.

Step 405: The counter value difference from Step 403 and 404 (the difference between the third count and the fourth count) represents the frequency and from this difference, a desired frequency deviation can be deduced, i.e., how many capacitors in the frequency deviation bank 210 should be switched on or off.

Note: In some embodiments, Step 403 and 404 can be exchanged (as can be Steps 303 and 304). Step 403 and 404 make the biggest capacitor change so that less counting time and a small counter can be used. Therefore, it is not required to turn all capacitors in the frequency deviation capacitor on or off without departing from the invention disclosure. A partial turn on or off of the capacitors in the frequency deviation capacitor bank 210 will increase the counting time and complexity of the counter, but the calibration principle still holds.

After the frequency modulation capacitor bank 210 is calibrated, the frequency change by turning on or off a particular capacitor is known. Due to the nonlinear nature of VCO frequency verse capacitor, certain compensation may be applied. For FSK and MSK signaling, the modulation is achieved by turning on and off a number of capacitors in the frequency deviation capacitor bank 210 during the symbol period and the on and off action does not change during the symbol period. For example, if the frequency deviation capacitor bank 210 comprises 50 capacitors 265 and each capacitor 265 corresponds to a 20 kHz frequency change from the above calibration, the frequency deviation capacitor bank 210 can be set to half its value, then when Symbol 1 is needed with 500 kHz deviation, 25 capacitors can be switched on while 25 capacitors can be switched off on for Symbol 0.

In the FSK/MSK case, the number on or off of capacitors in the frequency deviation bank is a fixed number during symbol period. However, if capacitor values can change during the symbol period, other types of frequency modulation, such as GFSK and GMSK, can be achieved. In the GFSK/GMSK case, the number of on or off capacitors is a varying number during a symbol period. This varying number depends on the Gaussian filter output and the frequency of capacitor change during a symbol period depends on the sampling rate.

The application discloses a device and method for frequency modulation based on two path modulation. Methods of calibrating the frequency deviation capacitor bank, improving frequency deviation accuracy due to the non-linear nature of the system, and methods of matching GFSK digital output for use in the frequency deviation capacitor bank are also disclosed. The DAC in the traditional upper path is replaced by a frequency deviation capacitor bank reducing current consumption, reducing component size, and removing noise from the system through the elimination of active components.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A two path direct frequency modulation system comprising:
a voltage controlled oscillator (VCO) comprising:
a frequency deviation capacitor bank including a first plurality of switchable capacitors; and
a VCO calibration capacitor bank including a second plurality of switchable capacitors;
a first path coupled to feed a digital control signal output from a baseband modulator to the first plurality of switchable capacitors and configured to control how many of the first plurality of switchable capacitors are turned on and how many of the first plurality of switchable capacitors are turned off; and
a second path comprising a serially coupled a charge pump, a loop filter and a Varactor of the VCO configured to control how many of the second plurality of switchable capacitors are turned on and how many of the second plurality of switchable capacitors are turned off;
wherein the VCO calibration capacitor bank determines VCO frequency and the frequency deviation capacitor bank determines data modulation.

2. The two path direct frequency modulation system of claim 1, wherein the frequency deviation capacitor bank is configured to modulate a data signal within the desired frequency band by adjusting how many switchable capacitors of the second plurality of switchable capacitors are switched on and how many switchable capacitors of the second plurality of switchable capacitors are switched off according to the digital signal.

3. The two path direct frequency modulation system of claim 2, wherein the frequency deviation capacitor bank is configured to modulate a data signal for Frequency Shift Keying (FSK) and/or Minimum Shift Keying (MSK) signaling within the desired frequency band by adjusting how many switchable capacitors of the second plurality of switchable capacitors are switched on and how many switchable capacitors of the second plurality of switchable capacitors are switched off before the symbol period and not changing how many switchable capacitors of the second plurality of switchable capacitors are switched on and how many switchable capacitors of the second plurality of switchable capacitors are off during the symbol period.

4. The two path direct frequency modulation system of claim 2, wherein the frequency deviation capacitor bank is configured to modulate a data signal for Gaussian frequency shift keying (GFSK) and/or Gaussian Minimum Shift Keying (GMSK) signaling within the desired frequency band by changing how many switchable capacitors of the second plurality of switchable capacitors are switched on and how many switchable capacitors of the second plurality of switchable capacitors are switched off while during the symbol period.

5. The two path direct frequency modulation system of claim 2, further comprising a counting unit configured to determine how many switchable capacitors of the second plurality of switchable capacitors are switched on and how many switchable capacitors of the second plurality of switchable capacitors are switched off.

6. The two path direct frequency modulation system of claim 2, further comprising a counting unit configured to determine how many switchable capacitors of the first plurality of switchable capacitors are switched on and how many switchable capacitors of the first plurality of switchable capacitors are switched off.

7. The two path direct frequency modulation system of claim 1 wherein the first plurality of switchable capacitors and the second plurality of switchable capacitors are of a same type.

8. A method of operating a two path direct frequency modulation system comprising a Varactor, voltage-controlled oscillator (VCO) calibration capacitor bank including a first plurality of switchable capacitors and a frequency deviation capacitor bank including a second plurality of switchable capacitors, the method comprising:
setting the Varactor to a predefined value;
setting the frequency deviation capacitor bank to a middle value of the frequency deviation capacitor bank;
calibrating the VCO and finding a corresponding VCO band after calibration;
recording quantity of cycles within a predetermined time to determine a first count;
switching on or off one of the first plurality of switchable capacitors and counting quantity of cycles with a predefined time to determine a second count;
determining a modulation number of on or off capacitors in the frequency deviation capacitor bank according to the first count, the second count, and/or the difference between the first and second counts to obtain a predefined frequency deviation; and
modulating a data signal at a desired frequency by switching on or off the modulation number of switchable capacitors of the second plurality of switchable capacitors.

9. The method of claim 8, wherein the frequency deviation capacitor bank is configured to modulate a data signal for Frequency Shift Keying (FSK) and/or Minimum Shift Keying (MSK) signaling within the desired frequency band by adjusting how many switchable capacitors of the second plurality of switchable capacitors are switched on and how many switchable capacitors of the second plurality of switchable capacitors are switched off before the symbol period and not adjusting how many switchable capacitors of the second plurality of switchable capacitors are switched on and how many switchable capacitors of the second plurality of switchable capacitors are the during the symbol period.

10. The method of claim 8, wherein the frequency deviation capacitor bank is configured to modulate a data signal for Gaussian frequency shift keying (GFSK) and/or Gaussian Minimum Shift Keying (GMSK) signaling within the desired frequency band by changing how many switchable capacitors of the second plurality of switchable capacitors are switched on and how many switchable capacitors of the second plurality of switchable capacitors are switched off while during the symbol period.

11. The method of claim 8 further comprising determining the modulation number using a lookup table.

12. A method of operating a two path direct frequency modulation system comprising a Varactor, voltage-controlled oscillator (VCO) calibration capacitor bank including a first plurality of switchable capacitors and a frequency deviation capacitor bank including a second plurality of switchable capacitors, the method comprising:
setting the Varactor to a predefined value;
setting the frequency deviation capacitor bank to a middle value of the frequency deviation capacitor bank and fixing a corresponding VCO band after calibration;
setting all of the second plurality of switchable capacitors to be off and recording a first quantity of cycles within a predetermined duration to determine a first count;
setting all of the second plurality of switchable capacitors to be on and recording a second quantity of cycles within a predefined duration to determine a second count;
determining a modulation number of on or off capacitors in the frequency deviation capacitor bank according to a difference between the first and second counts to obtain a predefined frequency deviation; and
modulating a data signal at a desired frequency by switching on or off the modulation number of switchable capacitors of the second plurality of switchable capacitors.

13. The method of claim 12, wherein the frequency deviation capacitor bank is configured to modulate a data signal for Frequency Shift Keying (FSK) and/or Minimum Shift Keying (MSK) signaling within the desired frequency band by adjusting how many switchable capacitors of the second plurality of switchable capacitors are switched on and how many switchable capacitors of the second plurality of switchable capacitors are switched off before the symbol period and not adjusting how many switchable capacitors of the second plurality of switchable capacitors are switched on and how many switchable capacitors of the second plurality of switchable capacitors are off during the symbol period.

14. The method of claim 12, wherein the frequency deviation capacitor bank is configured to modulate a data signal for Gaussian frequency shift keying (GFSK) and/or Gaussian Minimum Shift Keying (GMSK) signaling within the desired frequency band by changing how many switchable capacitors of the second plurality of switchable capacitors are switched on and how many switchable capacitors of the second plurality of switchable capacitors are switched off while during the symbol period.

15. The method of claim 12 further comprising determining the modulation number using a lookup table.
